(19) United States
(12) Patent Application Publication
(10) Pub. No.: US 2026/0107772 A1
(43) Pub. Date: Apr. 16, 2026

(54) SEMICONDUCTOR PACKAGE ASSEMBLY WITH DIRECT WATER COOLING SYSTEM

(71) Applicant: STATS ChipPAC Pte. Ltd., Singapore (SG)

(72) Inventors: JiSeon LEE, Incheon (KR); HeeSoo LEE, Incheon (KR)

(21) Appl. No.: 19/357,090

(22) Filed: Oct. 14, 2025

(30) Foreign Application Priority Data
Oct. 14, 2024 (CN) 202411431216.3

(51) Int. Cl. H01L 23/46; H01L 21/56; H01L 23/498; H01L 25/10

(52) U.S. Cl. CPC H10W 40/40; H10W 74/01; H10W 90/00; H10W 90/701; H10W 90/288; H10W 90/722

(57) ABSTRACT

A semiconductor package assembly, comprising: a first semiconductor package having at least one first electronic component exposed from its front surface; a second semiconductor package stacked on the first semiconductor package and having at least one second electronic component exposed from its front surface, wherein the first and second semiconductor packages define therebetween a first fluidic channel; and a lid stacked on the second semiconductor package; wherein the lid and the second semiconductor packages define therebetween a second fluidic channel to which the at least one second electronic component is exposed; wherein the second semiconductor package has openings passing therethrough to fluidly connect the first fluidic channel with the second fluidic channel, such that a coolant is capable of flowing within the first and second fluidic channels to dissipate heat generated by electronic components out of the semiconductor package assembly.

### TECHNICAL FIELD

The present application generally relates to semiconductor technologies, and more particularly, to a semiconductor package assembly with an interlayer cooling pathway, and a method for making a semiconductor package assembly.

### BACKGROUND OF THE INVENTION

The semiconductor industry is constantly faced with complex integration challenges as consumers want their electronics to be smaller, faster and higher performance with more and more functionalities packed into a single device. In some semiconductor packages, a Package-in-Package (PiP) or Package-on-Package (PoP) process is applied, which combines two or more integrated circuit (IC) packages together. The PiP or PoP devices can more efficiently use space, and reduce lengths of signal paths between the packages. In a typical PiP or PoP device, one or more pre-molded semiconductor packages may be mounted onto another semiconductor package through an interposer or other similar structures.

However, it is noted that certain electronic components such as logic circuit chips in the PiP or PoP devices may generate significant heat during operation, which may not be well dissipated to the external environment due to the compact package structure of the PiP or PoP devices. Therefore, a need exists for further improvement to semiconductor package assemblies with integrated electronic components.

### SUMMARY OF THE INVENTION

An objective of the present application is to provide a semiconductor package assembly with a direct cooling system.

According to an aspect of the present application, a semiconductor package assembly is disclosed. The semiconductor package assembly comprises: a first semiconductor package having at least one first electronic component exposed from its front surface; a second semiconductor package stacked on the first semiconductor package and having at least one second electronic component exposed from its front surface, wherein the first and second semiconductor packages define therebetween a first fluidic channel to which the at least one first electronic component is exposed; and a lid stacked on and covering the second semiconductor package; wherein the lid and the second semiconductor packages define therebetween a second fluidic channel to which the at least one second electronic component is exposed; wherein the second semiconductor package has openings passing therethrough to fluidly connect the first fluidic channel with the second fluidic channel, such that a coolant is capable of flowing within the first and second fluidic channels to dissipate heat generated by the at least one first electronic component and the at least one second electronic component out of the semiconductor package assembly.

According to another aspect of the present application, a method for making a semiconductor package assembly is provided. The method comprises: providing a first semiconductor package, wherein the first semiconductor package has at least one first electronic component exposed from its front surface; mounting a second semiconductor package on the first semiconductor package to form a first fluidic channel between the first and second semiconductor packages, wherein the at least one first electronic component is exposed to the first fluidic channel, and wherein the second semiconductor package comprises at least one second electronic component exposed from its front surface and openings passing therethrough; and stacking a lid on the second semiconductor package to cover the second semiconductor package and form a second fluidic channel between the second semiconductor package and the lid and in fluid connection with the first fluidic channel, wherein the at least one second electronic component is exposed to the second fluidic channel.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a semiconductor package assembly according to an embodiment of the present application.

FIG. 2 illustrates a semiconductor package assembly according to an embodiment of the present application.

FIG. 3 illustrate a semiconductor package assembly according to an embodiment of the present application.

FIGS. 4A to 4H illustrate a method for making a semiconductor package assembly according to an embodiment of the present application.

FIGS. 5A to 5B illustrate a method for making a semiconductor package assembly according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, conventional semiconductor package assemblies may not have satisfactory heat dissipation performance due to their compact structure as well as significant heat generated by electronic components encapsulated within the semiconductor package assemblies. To address the heat dissipation issue, the inventors of the present application have conceived incorporating into a semiconductor package assembly a direct cooling system to provide cooling for the internal electronic components. The direct cooling system may include a first fluidic channel and a second fluidic channel which are in fluid communication with each other to allow heat to be transferred from the electronic component exposed to the fluidic channels to a coolant fluid circulating within the fluidic channels. In this way, the heat dissipation performance of the semiconductor package assembly can be improved significantly.

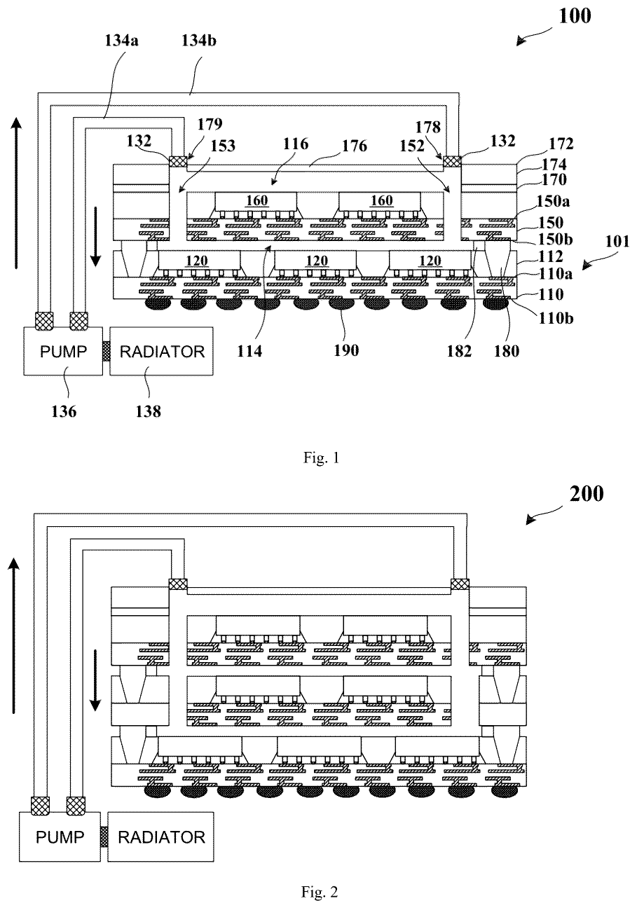

FIG. 1 illustrates a semiconductor package assembly 100 according to an embodiment of the present application. As shown in FIG. 1, the semiconductor package assembly 100 incorporates two semiconductor packages that are stacked together, and a lid stacked on top of the two semiconductor packages. It should be noted that although two semiconductor packages are illustrated in FIG. 1 as an example, more semiconductor packages may be integrated within the semiconductor package assembly 100, as desired. For example, three or more semiconductor packages may be stacked together, each occupying a layer of the semiconductor package assembly 100.

As shown in FIG. 1, the semiconductor package assembly 100 includes a first semiconductor package 101. The first semiconductor package 101 may include a first substrate 110, and at least one first electronic component 120 mounted on the first substrate 101. In some embodiments, each of the electronic component 120 may be a semiconductor die or a smaller semiconductor package which may be mounted on a front surface of the first substrate 101 via solder bumps or similar structures, or can be any other suitable electronic components such as capacitors, resistors, inductors, etc. An encapsulant layer 112 is formed on the front surface of the first substrate 101 to encapsulate the first electronic components 120. Preferably, the encapsulant layer 112 may expose respective front surfaces of one or more of the first electronic components 120, i.e., only lateral surfaces of the one or more first electronic components 120 are covered by the encapsulant layer 112. The exposed front surfaces of the one or more first electronic components 120 provide an interface or pathway for heat exchange between the first electronic components 120 and the exterior space thereof. As such, a front surface of the encapsulant layer 112 may be a part of a front surface 110a of the first semiconductor package 101, while the exposed front surfaces of the one or more first electronic components 120 may constitute another part of the front surface of the first semiconductor package 101. In some embodiments, the encapsulant layer 112 may be formed with an excess amount of a molding material over the first electronic components 120, which may later be attenuated (e.g., etched) to some extent to expose the front surfaces of the first electronic components 120. In some embodiments, the encapsulant layer 112 may be made, partially or in all, of a polymer composite material such as epoxy resin with filler, epoxy acrylate with filler, or polymer with proper filler.

Still referring to FIG. 1, the first semiconductor package 101 has the front surface 110a (facing upward in the direction shown in FIG. 1) and a back surface 110b that is opposite to the front surface 110a. Solder bumps 190 may be mounted onto the back surface 110b of the first substrate 110 to allow the entire semiconductor package assembly 100 to be mounted on or connected to an external device when needed. By way of example, the first substrate 110 may include a printed circuit board (PCB), a carrier substrate, a semiconductor substrate with electrical interconnections, a ceramic substrate, a laminate interposer, a strip interposer, a leadframe, or other suitable substrates. The first substrate 110 may include any structure on or in which an integrated circuit system can be fabricated. In some examples, the first substrate 110 may include redistribution structures having one or more dielectric layers and one or more conductive layers between and through dielectric layers. The conductive layers may define pads, traces and plugs through which electrical signals or voltages can be distributed horizontally and vertically across the redistribution structures.

The first electronic components 120 may include any of a variety of types of semiconductor dice, semiconductor packages, or discrete devices. For example, the first electronic components 120 may include a logic chip such as a central processing unit (CPU) or a graphics processing unit (GPU), a memory device such as a high bandwidth memory (HBM), a digital signal processor (DSP), a radiofrequency (RF) circuit, a wireless baseband system-on-chip (SoC) processor, a sensor, an application specific integrated circuit, etc. The first electronic components 120 may be passive components such as resistors, capacitors, inductors, switches, or any other suitable electronic devices. The first electronic components 120 are mounted on the front surface 110a of the first substrate 110. The first substrate 110 can provide support and connectivity for electronic components and devices mounted thereon. It can be appreciated that the first electronic components 120 may have different heights when they are mounted on the first substrate 110, of which the highest one may need cooling by the internal direct cooling system and thus be exposed.

The semiconductor package assembly 100 further includes a second semiconductor package which may be stacked on the first semiconductor package 101. In particular, the second semiconductor package may include a second substrate 150 and at least one second electronic component 160 mounted on the second substrate 150. The second substrate 150 has a front surface 150a and a back surface 150b opposite to the front surface 150a. In the embodiment, the second electronic components 160 is mounted on the front surface 150a of the second substrate 150. The second electronic components 160 may include any of a variety of types of semiconductor dice, semiconductor packages, or discrete devices, and may be mounted on the front surface 150a of the second substrate 150 via solder bumps or similar structures. In some other embodiments, other than those components on the front surface of the second substrate 150, one or more other electronic components may be mounted on the back surface 150b.

Continuing referring to FIG. 1, a set of connection structures 180 are formed between the first substrate 110 and the second substrate 150 to electrically connect the two substrates 110 and 150 and therefore the electronic components mounted thereon. In some embodiments, the connection structures 180 may be formed in a non-fluid region between the first and second semiconductor packages and electrically connecting the first and second semiconductor packages with each other. The non-fluid region may refer to a region of the semiconductor package assembly 100 where no fluid especially coolant may be filled. In an embodiment, the set of connection structures 180 may be solder bumps, while in some alternative embodiments, the set of connection structures 180 may be other interconnect components such as metal posts or e-bar modules. Besides electrically connecting the first and second semiconductor packages with each other, the connection structures 180 may provide mechanical support therebetween. In particular, the connection structures 180 may extend through the encapsulant layer 112 and protrude from the front surface of the encapsulant layer 112 (i.e., the front surface of the first semiconductor package 101). In this way, a gap may be formed between the first and second semiconductor packages. In other words, the set of connection structures 180 are so formed that the first and second semiconductor packages are spaced apart from each other to form a first fluidic channel 114. The first fluid channel 114 is in a fluid region of the semiconductor package assembly 100 where the coolant fluid may be filled and flow.

As aforementioned, the semiconductor package assembly 100 may be divided into the fluid region and the non-fluid region according to the filling and flowing of the coolant fluid. A sealing ring 182 is disposed between the first and second semiconductor packages, or particularly between the second substrate 150 and the encapsulant layer 112. The sealing ring 182 may enclose an entirety of the first fluidic channel 114 and separate the first fluidic channel 114 from the non-fluid region. As such undesired electrical connection and coolant leakage between the first fluidic channel 114 and other conductive structures can be avoided. For example, the sealing ring 182 may be made of an insulating polymer composite material such as epoxy resin.

In the embodiment, the second semiconductor package includes a first opening 152 and a second opening 153. The first opening 152 and the second opening 153 may be formed in a periphery area of the second semiconductor package and extend through the second semiconductor package, and thus provide pathways for the coolant fluid to flow into or out of the first fluidic channel 114 below the second semiconductor package. It can be appreciated that during operation, one of the openings 152 and 153 may serve primarily as an input for coolant fluid flowing into the first fluidic channel 114 while the other may serve primarily as an output for coolant fluid flowing out of the first fluidic channel 114. In some other embodiments, three or more openings may be formed in the second semiconductor package, and accordingly, a portion of the openings may serve as coolant input(s) and the other portion of the openings may serve as coolant output(s), depending primarily on a flow direction of the coolant fluid in the first fluidic channel 114.

Still referring to FIG. 1, a lid 172 is stacked on and cover the second semiconductor package. The lid 172 has a support portion 174 which is attached to the second semiconductor package and a fluid enclosing portion 176 with a thinner thickness than the support portion 174. The fluid enclosing portion 176 is spaced apart from the second semiconductor package to form a second fluidic channel 116. The second fluidic channel 116 allows for flowing of the coolant fluid at the front side of the second semiconductor package, similar as the first fluidic channel 114 at the back side of the second semiconductor package. An inlet 178 and an outlet 179 may pass through the lid 172 and be in fluid communication with the second fluidic channel 116. The inlet 178 can receive the coolant fluid from an external coolant container, and the outlet 179 can output the coolant fluid to the external coolant container. In some embodiments, the inlet 178 and the outlet 179 may be aligned with the first opening 152 and the second opening 153 respectively to allow the coolant fluid to circulate. In some alternative embodiments, the inlet 178 and the outlet 179 may be offset from the openings to avoid the coolant fluid from mainly circulating in the first fluidic channel 114. It can be appreciated that the lid 172 may include liquid crystal polymer, steel or other suitable materials. Moreover, the thinner fluid enclosing portion 176 corresponding to the second fluidic channel 116 may be formed in advance through an etching process, for example, before the lid 172 is attached to the second semiconductor package.

In some embodiments, an adhesive layer 170 may be formed between the second semiconductor package and the support portion 174 of the lid 172. The adhesive layer 170 may include materials such as epoxy resin or epoxy with silver filler etc. with high adhesion, low moisture absorption, and good mechanical properties, to prevent the coolant fluid in the second fluidic channel 116 from leaking to the external coolant container.

Still referring to FIG. 1, the first electronic components 120 can be exposed to the first fluidic channel 114, to allow heat exchange between the first electronic components 120 and the coolant fluid in the first fluidic channel 114. In this way, heat generated by the first electronic components 120 can be directly dissipated to the coolant fluid which circulates between inside and outside of the semiconductor package assembly 100. Similarly, the second electronic components 160 of the second semiconductor package can be exposed to the second fluidic channel 116, to allow heat generated by the second electronic components 160 to be directly dissipated to the external coolant container. Furthermore, the first opening 152 and the second opening 153 fluidly connect the first fluidic channel 114 with the second fluidic channel 116, such that the coolant fluid can flow within the fluid pathway including the first and second fluidic channels to dissipate heat generated by the internal electronic components out of the semiconductor package assembly.

It should be understood that only two fluidic channels are included in the embodiment shown in FIG. 1, but more fluidic channels can be formed in the semiconductor package assembly when more semiconductor packages are stacked as different layers or levels of the semiconductor package assembly. For example, FIG. 2 illustrates a semiconductor package assembly 200 according to an embodiment of the present application. As shown in FIG. 2, in the embodiment, three layers of semiconductor packages may be stacked together, with three fluidic channels formed therebetween or between the top semiconductor package and a lid of the semiconductor package assembly 200. The three fluidic channels may be in fluid communication with each other through respective openings that pass through the semiconductor packages. Also, in some embodiments, the semiconductor packages may be stacked together depending on the specific electronic components encapsulated in the packages, or particularly respective maximum junction temperatures of the electronic components. For example, a HBM die may withstand a maximum junction temperature of 85˜95 Centi-degrees, while a generic logic circuit die may withstand a maximum junction temperature of 120 Centi-degrees. In that case, the semiconductor package including the HBM die may be disposed closest to an inlet of the fluidic cooling pathway, while the semiconductor package including the generic logic circuit die may be disposed farthest away from the inlet.

As shown in FIG. 1, a pipe 134a is used to couple the outlet 179 of the lid 172 to the pump 136, and another pipe 134b is used to couple the inlet 178 of the lid 172 to the pump 136. According to the configuration of the pump 136, the pipe 134b can bring the coolant fluid into the fluidic region and the pipe 134a can bring the coolant fluid out of the fluidic region, thereby circulating the coolant fluid within the pipes 134a and 134b and the first fluidic channel 114 and the second fluidic channel 116. The pipes 134a and 134b may include polyvinyl chloride (PVC), polyurethane (PU), polyethylene terephthalate glycol (PETG), metal such as copper or aluminum, etc. Further, two valves 132 may be disposed at the inlet 178 and the outlet 179 of the lid 172 to regulate a flow rate of the coolant fluid within the first fluidic channel 114 and the second fluidic channel 116. For example, when the semiconductor package assembly 100 is operating with a high power, i.e., more heat may be generated during the operation, the valves 132 may be regulated to accelerate the flow rate of the coolant fluid. As shown in FIG. 1, a radiator 138 is coupled to the pump 136 to cool the coolant fluid when it comes into the pump 136. The radiator 138 may be a passive radiator or an active radiator, which can cool the coolant fluid down to a lower temperature. Therefore, the coolant fluid in the cooling pipe 130 may be circulated (represented by arrows in FIG. 1) and cooled down efficiently through the pump 136 and the radiator 138.

In some embodiments, referring to FIG. 1, a plurality of conductive bumps 190 are formed on a back surface 110b of the first substrate 110. In the example shown in FIG. 1, the conductive bumps 190 are illustrated as solder bumps, but the present application is not limited thereto. In some other embodiments, the conductive bumps 190 may include conductive pillars, copper balls, etc. In a case where the semiconductor package assembly 100 is mounted on an external device or substrate such as a printed circuit board (PCB), the conductive bumps 190 may be used for electrically connecting the semiconductor package assembly 100 to the external device or substrate.

FIG. 3 illustrates a semiconductor package assembly 300 according to an embodiment of the present application. For example, air may be introduced from the external environment into a first fluidic channel 314 and a second fluidic channel 316 through a cooling fluid input vent 378. In this way, air can bring heat generated by the first and second semiconductor packages, especially by first electronic components 320 exposed from the front surface of the first fluidic channel 314 and second electronic components 360 exposed from the front surface of the second fluidic channel 316, out of the semiconductor package assembly 300, for example, through a first opening 352 and a second opening 353 which pass through the second semiconductor package to a cooling fluid output vent 379. As such, the cooling fluid input vent 378 and the cooling fluid output vent 379 define together a cooling fluid pathway inside the semiconductor package assembly 300 to allow for a fluid flow from the cooling fluid input vent 378 to the cooling fluid output vent 379.

In some embodiments, a fan (not shown) may be mounted on the front surface of the lid 372 and at the cooling fluid input vent 378 to blow air into the cooling fluid pathway under the lid 372. The improved air flow within the fluid pathway can enhance heat dissipation from the first semiconductor package.

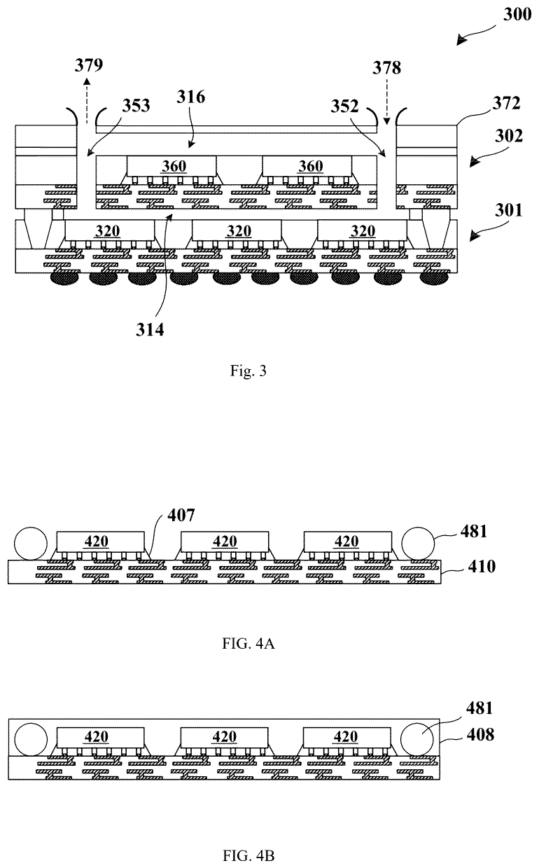

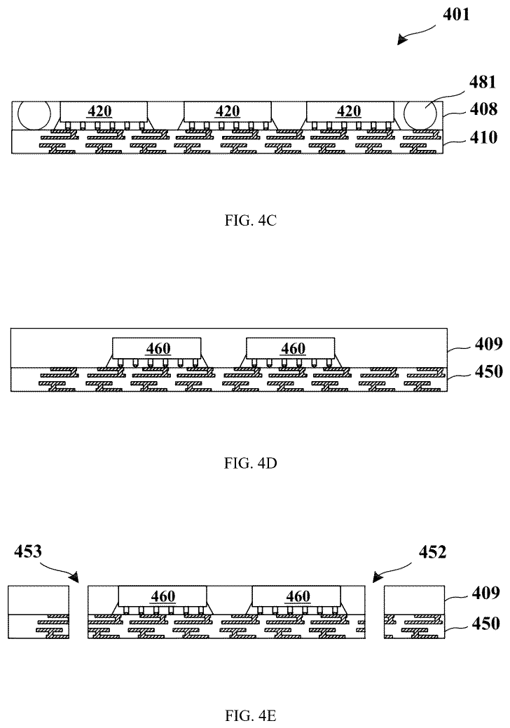

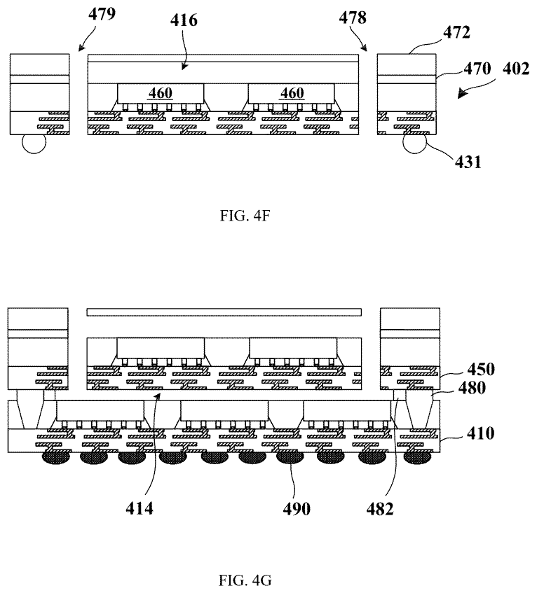

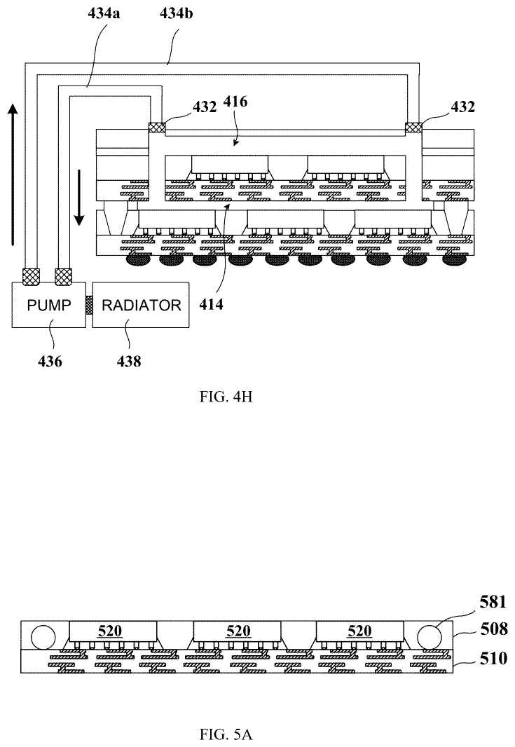

FIGS. 4A to 4H illustrate a method for making a semiconductor package assembly according to an embodiment of the present application. The method may be used to make the semiconductor package assembly 100 shown in FIG. 1, or may be used to make the semiconductor package assembly 200 shown in FIG. 2 or the semiconductor package assembly 300 shown in FIG. 3 with some modifications.

As shown in FIG. 4A, a first substrate 410 is provided, and at least one first electronic component 420 is mounted onto the first substrate 410 via solder bumps. A first set of solder bumps 481 may be mounted on a front surface of the first substrate 410. An underfill material 407 may be filled between the first electronic components 420 and the first substrate 410 and around the solder bumps under the first electronic components 420, to enhance the attachment of the first electronic components 420 to the first substrate 410.

Next as shown in FIG. 4B, an encapsulant layer 408 may be formed on the first substrate 410 to encapsulate the first electronic components 420 and the first set of solder bumps 481. For example, the encapsulant layer 408 may be formed using an injection molding process or a compression molding process. In some other embodiments, the encapsulant layer 408 may be formed using paste printing, transfer molding, liquid encapsulant molding, vacuum lamination, spin coating, or any other suitable process.

Next, as shown in FIG. 4C, an excess portion of the molding material of the encapsulant layer 408 that is higher than a front surface of the first electronic components 420 may be removed, for example, using a grinding process, to expose the front surface of the first electronic components 420 and the first set of solder bumps 481. The first substrate 410, the first electronic components 420 and the encapsulant layer 408 may together form a first semiconductor package 401, which will later be connected with other components.

Next, as shown in FIG. 4D, a second substrate 450 is provided, at least one second electronic component 460 is mounted onto the second substrate 450 via solder bumps. An encapsulant layer 409 may be formed on the second substrate 450 to encapsulate the second electronic components 460.

Next, as shown in FIG. 4E, an excess portion of the molding material of the encapsulant layer 409 that is higher than a front surface of the second electronic components 460 may be removed. Further, a first opening 452 and a second opening 453 may be formed through the second substrate 450 and the encapsulant layer 409. The first opening 452 and the second opening 453 may be formed using laser drilling, mechanical drilling, or other suitable processes. The first opening 452 and the second opening 453 can provide pathways for fluidic channels later described.

Next, as shown in FIG. 4F, a lid 472 is stacked on the second semiconductor package 402 via an adhesive layer 470 to cover the second semiconductor package 402 and form a second fluidic channel 416 between the second semiconductor package 402 and the lid 472. The second electronic components 460 are exposed to the second fluidic channel 416. A second set of solder bumps 431 may be mounted on a back surface of the second semiconductor package 402 to function as an interface between the second semiconductor package 402 and the first semiconductor package 401. Further, the lid 472 has an inlet 478 and an outlet 479 passing through and in fluid communication with the second fluidic channel 416.

Next, as shown in FIG. 4G, the first and second set of solder bumps may be connected together and reflowed to form a set of connection structures 480 between the first and second semiconductor packages. The connection structures 480 may space the first and second semiconductor packages apart from each other to form a first fluidic channel 414. A sealing ring 482 may be formed on the second substrate 450 which is at the same side as the connection structures 480 to separate the fluidic region and the connection structures 480 from each other. Afterwards, a plurality of conductive bumps 490 are formed on the back surface of the first substrate 410. In the example shown in FIG. 4G, the conductive bumps 490 are illustrated as solder bumps, but the present application is not limited thereto. In some other embodiments, the conductive bumps 490 may include conductive pillars, copper balls, micro bumps, etc.

Next, as shown in FIG. 4H, a pump 436 is coupled to the semiconductor package assembly, which is in fluid communication with the first fluidic channel 414 and the second fluidic channel 416 through cooling pipes 434a and 434b to circulate the coolant fluid within the first and second fluidic channels. Further, a radiator 438 is coupled with the pump 436 to cool the coolant fluid. Two valves 432 are mounted in the cooling pipes 434a and 434b to regulate the flow of the coolant fluid within the first and second fluidic channels.

After the various steps shown in FIGS. 4A to 4H, the semiconductor package assembly can be obtained.

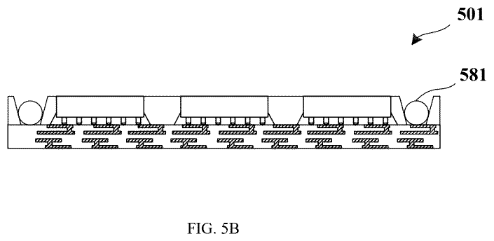

FIGS. 5A to 5B illustrate another optional method for making a first semiconductor package assembly. The method may be used to make the semiconductor package assembly 100 shown in FIG. 1, or may be used to make the semiconductor package assembly 200 shown in FIG. 2 or the semiconductor package assembly 300 shown in FIG. 3.

As shown in FIG. 5A, a first encapsulant layer 508 may be formed on a first substrate 510 to encapsulate at least one first electronic component 520 and a first set of solder bumps 581. Respective top surfaces of the at least one first electronic component 520 are exposed from the first encapsulant layer 508. Next, a portion of the first encapsulant layer 508 is removed by methods such as laser drilling, mechanical drilling, or other suitable processes to expose the first set of solder bumps 581, as shown in FIG. 5B.

After the steps shown in FIGS. 5A to 5B, the first semiconductor package 501 can be obtained and may be stacked to the second semiconductor package, which is the same as that shown form FIG. 4C to FIG. 4H and will not be repeated here.

The discussion herein includes numerous illustrative figures that show various portions of a semiconductor package assembly with a direct cooling system and a method for making such semiconductor package assembly. For illustrative clarity, such figures do not show all aspects of each example semiconductor package. Any of the example packages provided herein may share any or all characteristics with any or all other packages provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package assembly, comprising:
a first semiconductor package having at least one first electronic component exposed from its front surface;
a second semiconductor package stacked on the first semiconductor package and having at least one second electronic component exposed from its front surface, wherein the first and second semiconductor packages define therebetween a first fluidic channel to which the at least one first electronic component is exposed; and
a lid stacked on and covering the second semiconductor package; wherein the lid and the second semiconductor packages define therebetween a second fluidic channel to which the at least one second electronic component is exposed;
wherein the second semiconductor package has openings passing therethrough to fluidly connect the first fluidic channel with the second fluidic channel, such that a coolant is capable of flowing within the first and second fluidic channels to dissipate heat generated by the at least one first electronic component and the at least one second electronic component out of the semiconductor package assembly.

2. The semiconductor package assembly of claim 1, further comprising:
a set of connection structures mounted between the first and second semiconductor packages and electrically connecting the first and second semiconductor packages with each other; wherein the set of connection structures are so formed that the first and second semiconductor packages are spaced apart from each other to form the first fluidic channel.

3. The semiconductor package assembly of claim 2, wherein the first semiconductor package comprises a first substrate where the at least one first electronic component is mounted, and wherein the set of connection structures are mounted on and electrically connected with the first substrate.

4. The semiconductor package assembly of claim 2, wherein the first semiconductor package has a fluid region where the first fluidic channel is formed and a non-fluid region where the set of connection structures is mounted, and wherein the semiconductor package assembly further comprises a sealing ring disposed between the first and second semiconductor packages and for enclosing the fluid region and separating the fluid region from the non-fluid region.

5. The semiconductor package assembly of claim 2, wherein the second semiconductor package comprises a second substrate where the at least one second electronic component is mounted, and wherein the set of connection structures are electrically connected with the second substrate.

6. The semiconductor package assembly of claim 1, further comprising:
an adhesive layer formed between the second semiconductor package and the lid.

7. The semiconductor package assembly of claim 2, wherein the lid comprises a support portion which is connected to the second semiconductor package via the adhesive layer, and a fluid portion which is spaced apart from the second semiconductor package to form the second fluidic channel.

8. The semiconductor package assembly of claim 7, wherein the lid has a thinner thickness in the fluid portion than in the support portion.

9. The semiconductor package assembly of claim 1, wherein the lid comprises an inlet and an outlet passing therethrough and in fluid communication with the second fluidic channel, wherein the inlet is configured for receiving the coolant and the outlet is configured for outputting the coolant.

10. The semiconductor package assembly of claim 1, further comprising:
a pump in fluid communication with the first and second fluid channels through a cooling pipe to circulate the coolant within the first and second fluid channels; and
a radiator in fluid communication with the pump to cool the coolant which is out of the semiconductor package assembly.

11. The semiconductor package assembly of claim 10, further comprises:
two valves mounted in the cooling pipe to regulate the flow of the coolant within the first and second fluid channels.

12. The semiconductor package assembly of claim 1, further comprising:
at least a third semiconductor package mounted between the first and second semiconductor packages, wherein the first semiconductor package and the third semiconductor package define therebetween at least a fluidic channel to which the at least one first electronic component is exposed.

13. A method for forming a semiconductor package assembly, comprising:
providing a first semiconductor package, wherein the first semiconductor package has at least one first electronic component exposed from its front surface;
mounting a second semiconductor package on the first semiconductor package to form a first fluidic channel between the first and second semiconductor packages, wherein the at least one first electronic component is exposed to the first fluid channel, and wherein the second semiconductor package comprises at least one second electronic component exposed from its front surface and openings passing therethrough; and
stacking a lid on the second semiconductor package to cover the second semiconductor package and form a second fluidic channel between the second semiconductor package and the lid and in fluid connection with the first fluid channel, wherein the at least one second electronic component is exposed to the second fluidic channel.

14. The method of claim 13, wherein before the step of mounting a second semiconductor package on the first semiconductor package, the method further comprises:
forming a first set of solder bumps on a first substrate of the first semiconductor package;
forming a first encapsulant layer on the first substrate to encapsulate the at least one first electronic component and the first set of solder bumps;
removing a portion of the first encapsulant layer to expose respective top surfaces of the at least one first electronic component and the first set of solder bumps;
forming a second set of solder bumps on a second substrate of the second semiconductor package, wherein the second set of solder bumps are on opposite sides of the second substrate; and
connecting and reflowing the first and second set of solder bumps to form a set of connection structures between the first and second semiconductor packages, wherein the first and second semiconductor packages are spaced apart from each other by the set of connection structures to form the first fluidic channel.

15. The method of claim 13, wherein before the step of mounting a second semiconductor package on the first semiconductor package, the method further comprises:
forming a first set of solder bumps on a first substrate of the first semiconductor package;
forming a first encapsulant layer on the first substrate to encapsulate the at least one first electronic component and the first set of solder bumps, wherein respective top surfaces of the at least one first electronic component is exposed from the first encapsulant layer; removing a portion of the first encapsulant layer to expose the first set of solder bumps;
forming a second set of solder bumps on a second substrate of the second semiconductor package, wherein the second set of solder bumps are on opposite sides of the second substrate; and
connecting and reflowing the first and second set of solder bumps to form a set of connection structures between the first and second semiconductor packages, wherein the first and second semiconductor packages are spaced apart from each other by the set of connection structures to form the first fluidic channel.

16. The method of claim 14, wherein before the step of forming a second set of solder bumps on a second substrate of the second semiconductor package, the method further comprises forming a sealing ring between the first and second semiconductor packages; and
forming a sealing ring on the second substrate which is at the same side as the second set of solder bumps to separate the openings and the second set of solder bumps from each other.

17. The method of claim 13, wherein the step of stacking a lid on the second semiconductor package further comprises:
forming an adhesive layer on a bottom surface of the lid; and
attaching the lid onto the second semiconductor package via the adhesive layer.

18. The method of claim 13, further comprising:
coupling a pump in fluid communication with the first and second fluid channels through a cooling pipe to circulate the coolant within the first and second fluid channels; and
coupling a radiator with the pump to cool the coolant fluid.

19. The method of claim 13, further comprises:
mounting two valves in the cooling pipe to regulate the flow of the coolant within the first and second fluid channels.

20. The method of claim 13, further comprising:
mounting at least a third semiconductor package between the first and second semiconductor packages, wherein defining at least a fluidic channel between the first and at least a third semiconductor packages with at least one first electronic component exposed in it.
